(19) United States
(12) Patent Application Publication
(10) Pub. No.: US 2019/0011506 A1
(43) Pub. Date: Jan. 10, 2019

(54) MALFUNCTION DETECTION APPARATUS CAPABLE OF DETECTING ACTUAL MALFUNCTIONING DEVICE NOT DUE TO ABNORMAL INPUT VALUES

(71) Applicant: Mitsubishi Electric Corporation, Chiyoda-ku (JP)

(72) Inventors: Shoichi KOBAYASHI, Chiyoda-ku (JP); Wataru TSUJITA, Chiyoda-ku (JP); Toshihiro WADA, Chiyoda-ku (JP); Tomoki TAKEGAMI, Chiyoda-ku (JP)

(73) Assignee: Mitsubishi Electric Corporation, Chiyoda-ku (JP)

(21) Appl. No.: 16/066,357

(22) PCT Filed: Dec. 1, 2016
(86) PCT No.: PCT/JP2016/085765

§ 371 Date: Jun. 27, 2018

(30) Foreign Application Priority Data
Jan. 20, 2016 (JP) 2016-008738

(51) Int. Cl. G01R 31/36; H01M 10/48; G06K 9/62

(52) U.S. Cl. CPC G01R 31/3682; H01M 10/486; G06K 9/6269; G01R 31/3648; H01M 10/482

(57) ABSTRACT

A first classification circuit obtains first measured values from each of devices, the first measured values of the device including at least one input value to the device and at least one output value from the device, and classifies the first measured values of the devices into normal first measured values and outlier first measured values using the OCSVM (One Class nu-Support Vector Machine). A second classification circuit obtains second measured values from each of devices, the second measured values of the device including at least one input value to the device, and classifies the second measured values of the devices into normal second measured values and outlier second measured values using the OCSVM. A determination circuit determines a device having the outlier first measured values and the normal second measured values, to be a malfunctioning device.

### TECHNICAL FIELD

The present invention relates to a malfunction detection apparatus for a system including a plurality of devices of, for example, substantially the same type or class, and a plurality of sensors for measuring certain physical quantities of the devices, the malfunction detection apparatus detecting a malfunctioning device in the system based on data indicating conditions of the devices collected from the sensors. The present invention also relates to a malfunction detection system including such a plurality of devices, a plurality of sensors, and a malfunction detection apparatus.

### BACKGROUND ART

In recent years, for a system including a large number of devices, there is an increased need for a technique of effectively managing and operating the devices, by using a large number of sensors corresponding to the devices to collect and analyze data indicating conditions of the devices. One example of such a system is a battery system including a plurality of secondary battery cells. If a single secondary battery cell, such as a lithium ion battery, has insufficient battery capacity, input and output currents, and voltage, then a large number of secondary battery cells are combined in series or in parallel to be used as a battery system with a large capacity, large input and output currents, and a high voltage. Such a battery system may be mounted on, for example, a railway vehicle, and may be used for drive, drive assist, or regeneration storage. In this case, the battery system is configured to generate an output voltage of, for example, 600 V, by connecting a plurality of secondary battery cells in series, and to support a large output current required for driving an electric motor, and a large input current required for receiving regenerative power.

In such a battery system, all the secondary battery cells of the battery system should be in normal conditions. If any one of the secondary battery cells is in abnormal conditions, then the entire battery system and a device(s) connected thereto may fail. Therefore, the malfunction of the secondary battery cell should be detected immediately. In such a battery system, it is considered that most of the secondary battery cells are in normal conditions, and a very small number of secondary battery cells may in abnormal conditions. That is, in the entire battery system, it is required to detect a very small number of secondary battery cells operating in a manner different from that of most of secondary battery cells.

The background art of the present invention includes, for example, the invention of Patent Document 1. Patent Document 1 discloses an abnormality sign detecting method for detecting a sign of abnormality, by processing a plurality of pieces of sensor information for normal conditions using a one class support vector machine, the sensor information obtained by measuring a device under test in normal operating conditions using a plurality of sensors, to extract an combination of pieces of exceptional sensor information. For example, Non-Patent Document 1 also discloses a one class support vector machine.

### CITATION LIST

### Patent Documents

PATENT DOCUMENT1: Japanese Patent Laid-open Publication No. 2005-345154 (page 3 lines 8 to 11, FIG. 2)

### Non-Patent Documents

NON-PATENT DOCUMENT1: Shotaro AKAHO, “Kernel Tahenryou Kaiseki (Kernel Multivariate Analysis)”, published by Iwanami Shoten, pages 106 to 111, Nov. 27, 2008

### SUMMARY OF INVENTION

### Technical Problem

The method of Patent Document 1 may be applied to a system including a large number of devices (e.g., a battery system including a plurality of secondary battery cells). According to the method of Patent Document 1, even when detecting an exceptional sensor value for a device, it is not possible to distinguish between an abnormal sensor value due to malfunction of the device itself, and an abnormal sensor value due to a cause other than the device. Hence, it may deteriorate the accuracy in detecting the malfunction of the device.

An object of the present invention is to provide a malfunction detection apparatus capable of detecting malfunction of a device with higher accuracy than that of the prior art. Another object of the present invention is to provide a malfunction detection system including such a malfunction detection apparatus.

### Solution to Problem

According to an aspect of the present invention, a malfunction detection apparatus for detecting a malfunctioning device among a plurality of devices is provided. The malfunction detection apparatus includes: a first classification circuit, a second classification circuit, and a determination circuit. The first classification circuit obtains first measured values from each one device of the plurality of devices, the first measured values of the one device including at least one input value to the one device and at least one output value from the one device, and classifies the first measured values of the plurality of devices into normal first measured values and outlier first measured values using a predetermined multivariable analysis method. The second classification circuit obtains second measured values from each one device of the plurality of devices, the second measured values of the one device including at least one input value to the one device, and classifies the second measured values of the plurality of devices into normal second measured values and outlier second measured values using the multivariable analysis method. The determination circuit determines a device having the outlier first measured values and the normal second measured values, to be a malfunctioning device, among the plurality of devices.

### Advantageous Effects of Invention

The malfunction detection apparatus according to the aspect of the present invention is capable of detecting malfunction of a device with higher accuracy than that of the prior art.

### BRIEF DESCRIPTION OF DRAWINGS

FIG. 1 is a block diagram showing a configuration of a malfunction detection system according to a first embodiment of the present invention.

FIG. 2 is a diagram illustrating a relationship between input values and output values for devices 100-1 to 100-N of FIG. 1.

FIG. 3 is a diagram illustrating operation of a first classification circuit 112 of FIG. 1.

FIG. 4 is a diagram illustrating operation of a second classification circuit 113 of FIG. 1.

FIG. 5 is a table showing an example of determination made by a determination circuit 114 of FIG. 1.

FIG. 6 is a block diagram showing an exemplary application of the malfunction detection system of FIG. 1 to a system including trains 200-1 and 200-2.

FIG. 7 is a block diagram showing a configuration of a malfunction detection system according to a second embodiment of the present invention.

FIG. 8 is a table showing a first example of determination made by a determination circuit 114 according to a third embodiment of the present invention.

FIG. 9 is a table showing a second example of determination made by the determination circuit 114 according to the third embodiment of the present invention.

### DESCRIPTION OF EMBODIMENTS

Hereinafter, malfunction detection systems according to embodiments of the present invention will be described with reference to the drawings.

### First Embodiment

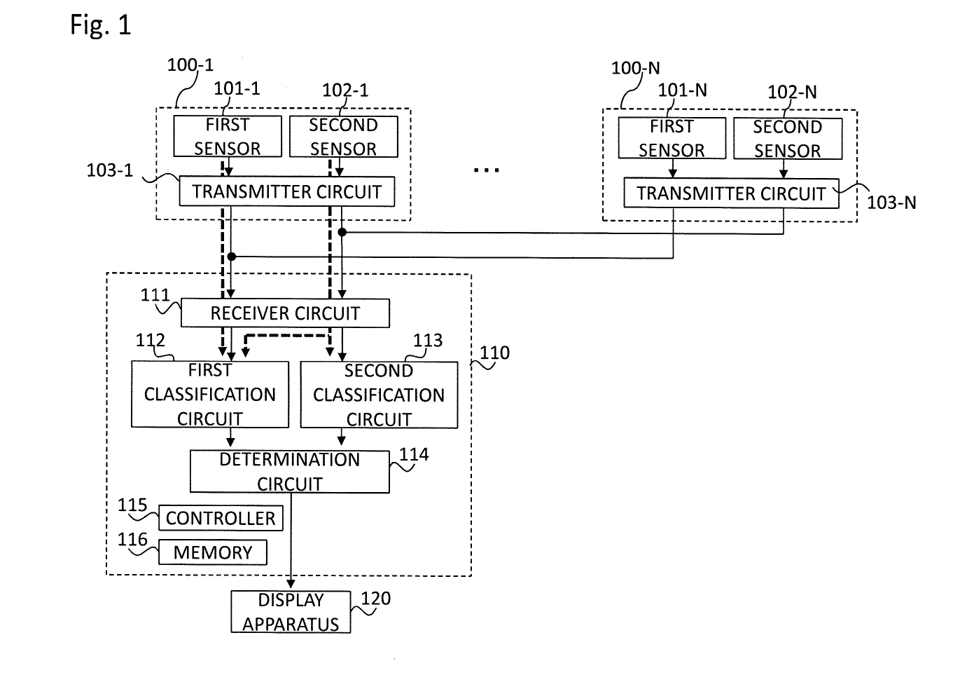

FIG. 1 is a block diagram showing a configuration of a malfunction detection system according to a first embodiment of the present invention. The malfunction detection system of FIG. 1 includes a plurality of devices 100-1 to 100-N, a malfunction detection apparatus 110, and a display apparatus 120.

The plurality of devices 100-1 to 100-N are of, for example, substantially the same type or class. In the present specification, each of the devices 100-1 to 100-N has a specific relationship between physical quantities inputted to the device (hereinafter referred to as “input values”), and physical quantities outputted from the device (hereinafter referred to as “output values”). The physical quantities inputted to the device determine operational conditions of the device, and the device produces an output value in accordance with the input value. The physical quantities inputted to the device are physical quantities affecting the operation of the device, including conditions of an environment containing the device. The physical quantities outputted from the device are physical quantities occurring or varying as a result of operation of the device. Specifically, each of the devices 100-1 to 100-N is, for example, a secondary battery cell or a motor device. In the case of the secondary battery cell, the input values of the secondary battery cell are a charging/discharging current, a charged percentage, and an air temperature (ambient temperature) of the secondary battery cell. The output values of the secondary battery cell are a terminal voltage and a temperature of the secondary battery cell (a temperature of the secondary battery cell itself). While the charged percentage varies as a result of input of the charging/discharging current, the charged percentage is regarded here as a physical quantity affecting the operation of the secondary battery cell. In the case of the motor device, the physical quantities inputted to the motor device are an input current, an input voltage, and an air temperature of the motor device. The physical quantities outputted from the motor device are a rotational speed, operation sound, vibration, and a temperature of the motor device.

The devices 100-1 to 100-N include first sensors 101-1 to 101-N, second sensors 102-1 to 102-N, and transmitter circuits 103-1 to 103-N, respectively. Their configuration and operation will be described below with reference to the device 100-1.

The first sensor 101-1 measures at least one physical quantity outputted from the device 100-1, namely at least one output value from the device 100-1, and transmits the measured output value(s) to the malfunction detection apparatus 110 via the transmitter circuit 103-1. The second sensor 102-1 measures at least one physical quantity inputted to the device 100-1, namely at least one input value to the device 100-1, and transmits the measured input value(s) to the malfunction detection apparatus 110 via the transmitter circuit 103-1. The transmitter circuit 103-1 is connected to the malfunction detection apparatus 110 via a wired or wireless network. The transmitter circuit 103-1 may transmit the output values and the input values of the device 100-1 as analog data to the malfunction detection apparatus 110, or may transmit those values as A/D converted digital data to the malfunction detection apparatus 110. In addition, when the device 100-1 measures the output values and the input values for the purpose of controlling the device 100-1 itself, the transmitter circuit 103-1 may output the output values and input values as analog data or digital data to the malfunction detection apparatus 110.

The other devices 100-2 to 100-N are also configured and operate in a manner similar to that of the device 100-1.

The malfunction detection apparatus 110 detects a malfunctioning device among the plurality of devices 100-1 to 100-N. The malfunction detection apparatus 110 includes a receiver circuit 111, a first classification circuit 112, a second classification circuit 113, a determination circuit 114, a controller 115, and a memory 116.

The receiver circuit 111 receives, from each of the devices 100-1 to 100-N, the output values and the input values of the device. The receiver circuit 111 passes the output values of the devices 100-1 to 100-N (the measured results of the first sensors 101-1 to 101-N) to the first classification circuit 112. In addition, the receiver circuit 111 passes the input values of the devices 100-1 to 100-N (the measured results of the second sensors 102-1 to 102-N) to both the first classification circuit 112 and the second classification circuit 113.

The first classification circuit 112 obtains, from each of the plurality of devices 100-1 to 100-N, the output values and the input values of the device as the first measured values of the device. Using a predetermined multivariable analysis method, the first classification circuit 112 classifies the first measured values of the devices 100-1 to 100-N into normal first measured values (most values having characteristics similar to each other), and outlier first measured values (a very small number of values considered as abnormal values).

In the present embodiment, a one class nu-support vector machine (hereinafter referred to as “OCSVM”) is used for classification into normal values and outlier values. OCSVM is one of multivariable analysis methods, and is applicable to a nonlinear system. Since OCSVM itself is well known and, for example, described in detail in Non-Patent Document 1, OCSVM will be briefly described in the present specification.

It is assumed that for each of the devices 100-1 to 100-N, the first measured values constitute a set of M values in total, including at least one output value and at least one input value. x⁽ⁿ⁾ (1≤n≤N) denotes an M-dimensional vector associated with each of the plurality of devices 100-1 to 100-N, the vector consisting of the first measured values of the device as its component. Here, we introduce the following discriminant function f(x) using a predetermined real-valued kernel function k(u, v), which represents a closeness between two M-dimensional vectors u and v.

$$f ( x ) {\sum }_{n = 1}^{N} {α}_{n} k ( {x}^{( n )} , x ) \qquad [ Mathematical Expression 1 ]$$

Here, α₁, . . . , α_{N} are weighting parameters. x denotes one of the vectors x⁽¹⁾, . . . , x^{(N)} of the first measured values.

For each of the vectors x⁽¹⁾, . . . , x^{(N)} of the first measured values, if the discriminant function value f(x⁽ⁿ⁾) is equal to or more than a positive threshold p, then the first measured values are classified as normal values; if the discriminant function value f(x⁽ⁿ⁾) is smaller than the threshold ρ, then the first measured values are classified as outlier values.

The parameters α₁, . . . , α_{N} and the threshold ρ are determined as follows.

As a loss function, we introduce the following equation.

r_{ρ}(f(x))=max(0,ρ−f(x)) [Mathematical Expression 2]

Considering the criterion of increasing the threshold ρ while reducing the loss indicated by this loss function, the problem is reformulated as the following optimization problem.

$${min}_{α , ρ} \frac{1}{N} {\sum }_{n = 1}^{N} {r}_{ρ} ( f ( {x}^{( n )} ) ) + \frac{1}{2} {α}^{T} K α - v ρ \qquad [ Mathematical Expression 3 ]$$

Here, the matrix K and the vector α are given as follows.

$$[ Mathematical Expression 4 ]$$

$$K = ( \begin{matrix}k ( {x}^{( 1 )} , {x}^{( 1 )} ) & k ( {x}^{( 2 )} , {x}^{( 1 )} ) & … & k ( {x}^{( N )} , {x}^{( 1 )} ) \\ k ( {x}^{( 1 )} , {x}^{( 2 )} ) & k ( {x}^{( 2 )} , {x}^{( 2 )} ) & … & k ( {x}^{( N )} , {x}^{( 2 )} ) \\ ⋮ & ⋮ & ⋱ & ⋮ \\ k ( {x}^{( 1 )} , {x}^{( N )} ) & k ( {x}^{( 2 )} , {x}^{( N )} ) & … & k ( {x}^{( N )} , {x}^{( N )} )\end{matrix} ) \\ [ Mathematical Expression 5 ]$$

$$α = ( {α}_{1} , … , {α}_{N} )$$

ν is a predetermined constant that specifies the upper limit of a ratio of the discriminant function values exceeding a margin for classification.

Using Mathematical Expression 3, the parameters α₁, . . . , α_{N} and the threshold ρ are determined. The discriminant function f(x) is determined by determining the parameters α₁, . . . , α_{N}. Using the discriminant function f(x) and the threshold ρ, the first classification circuit 112 classifies the first measured values of the respective devices 100-1 to 100-N into the normal first measured values and the outlier first measured values.

The second classification circuit 113 acquires, from each of the plurality of devices 100-1 to 100-N, the input values of the device as the second measured values of the device. Using the predetermined multivariable analysis method, the second classification circuit 113 classifies the second measured values of the devices 100-1 to 100-N into the normal second measured values and the outlier second measured values. The second classification circuit 113 may use the same multivariable analysis method (e.g., OCSVM) as that used in the first classification circuit 112. When the second classification circuit 113 uses the OCSVM, the discriminant function and the threshold are calculated for vectors consisting of the second measured values as their components, instead of the vectors consisting of the first measured values as their components.

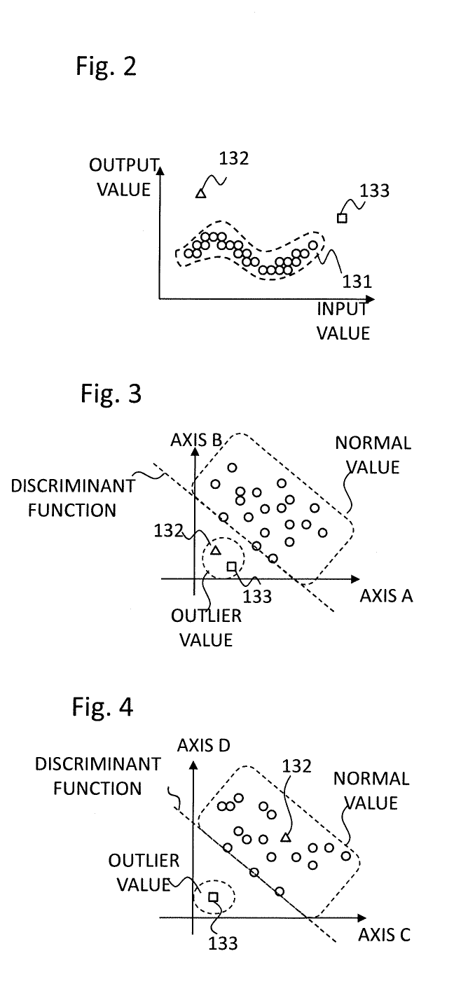

FIG. 2 is a diagram illustrating a relationship between input values and output values for the devices 100-1 to 100-N of FIG. 1. FIG. 2 shows a set of exemplary measurements, and we now explain outlier values to be extracted by the OCSVM with reference to FIG. 2. For ease of explanation, FIG. 2 shows the input values along the horizontal axis as a one-dimensional quantity, and also shows the output values along the vertical axis as a one-dimensional quantity.

Among the set of measured values shown in FIG. 2, the majority are normal measured values 131, but exceptionally, the set includes a measured value 132 corresponding to malfunction of the device itself, and a measured value 133 corresponding to abnormal input values. The normal measured values 131 are obtained, when the device itself is properly functioning and the normal input value is provided to the device. The measured value 132 corresponding to malfunction of the device itself is obtained, when the device itself is malfunctioning and an abnormal output value occurs even though the normal input value is provided to the device. The measured value 133 corresponding to the abnormal input values is obtained, when the device itself is properly functioning and an abnormal input value is provided to the device.

Here, for the purpose of comparison, we will consider a case of detecting malfunctioning secondary battery cells from a plurality of secondary battery cells using the conventional method (e.g., Patent Document 1). A secondary battery cell can be regarded as a device which produces an output value (e.g., a terminal voltage) conditioned on corresponding input values (e.g., charging current, charged percentage, air temperature). That is, the secondary battery cell is regarded as a device having inputs and outputs, in which there is a specific relationship between measured input values and measured output values, the specific relationship of a malfunctioning secondary battery cell being different from that of a normal secondary battery.

When the same input values are provided to a majority number of normal secondary battery cells and a very small number of malfunctioning secondary battery cells, the majority number of normal secondary battery cells produce output values having characteristics similar to each other, and only the small number of abnormal secondary battery cells produce different output values. Therefore, by obtaining the input values and the output values from each of the secondary battery cells, and applying the one class support vector machine to the input values and output values, the output values are classified into the majority number of normal output values and the small number of abnormal output values.

However, for example, when charging currents of the secondary battery cells are different due to, for example, different operating conditions of load apparatuses connected to the secondary battery cells, the input value of some secondary battery cells may be outlier values, which are different from the input values of the majority number of the secondary battery cells. In this case, even when the secondary battery cells themselves are properly functioning, the input values and the output values of the secondary battery cell with outlier input values would be different from the input values and the output values of the secondary battery cell with non-outlier input values. According to the conventional method, these are detected as exceptional input values and output values. Therefore, when the input value is an outlier value, a normal secondary battery cell may be incorrectly determined as a malfunctioning secondary battery cell.

FIG. 3 is a diagram illustrating the operation of the first classification circuit 112 of FIG. 1. The first classification circuit 112 determines a discriminant function and a threshold, by applying the OCSVM to a set of combinations of the input value and the output value (first measured values) shown in FIG. 2. The discriminant function and the threshold determine a hyperplane in a feature space corresponding to the kernel function. Referring to FIG. 3, the feature space is a two-dimensional space spanned by axes A and B, and a straight line in this two-dimensional space classifies normal values and outlier values. The first classification circuit 112 cannot distinguish between the measured value 132 corresponding to malfunction of the device itself, and the measured value 133 corresponding to abnormal input values, and classifies both of them into outlier values. Therefore, when only using the first classification circuit 112, it may incorrectly determine that the device itself is malfunctioning, even when the device itself is properly functioning.

The malfunction detection apparatus 110 of FIG. 1 further includes the second classification circuit 113, and the second classification circuit 113 determines a discriminant function and a threshold, by applying the OCSVM to a set of input values (second measured values) shown in FIG. 2. FIG. 4 is a diagram illustrating the operation of the second classification circuit 113 of FIG. 1. Referring to FIG. 4, the feature space is a two-dimensional space spanned by axes C and D, and a straight line in this two-dimensional space classifies normal values and outlier values. The second classification circuit 113 classifies the measured value 132 corresponding to malfunction of the device itself, as normal values, and classifies only the measured value 133 corresponding to the abnormal input values, as outlier values. Therefore, it is possible to distinguish between the measured value 132 corresponding to malfunction of the device itself, and the measured value 133 corresponding to the abnormal input values.

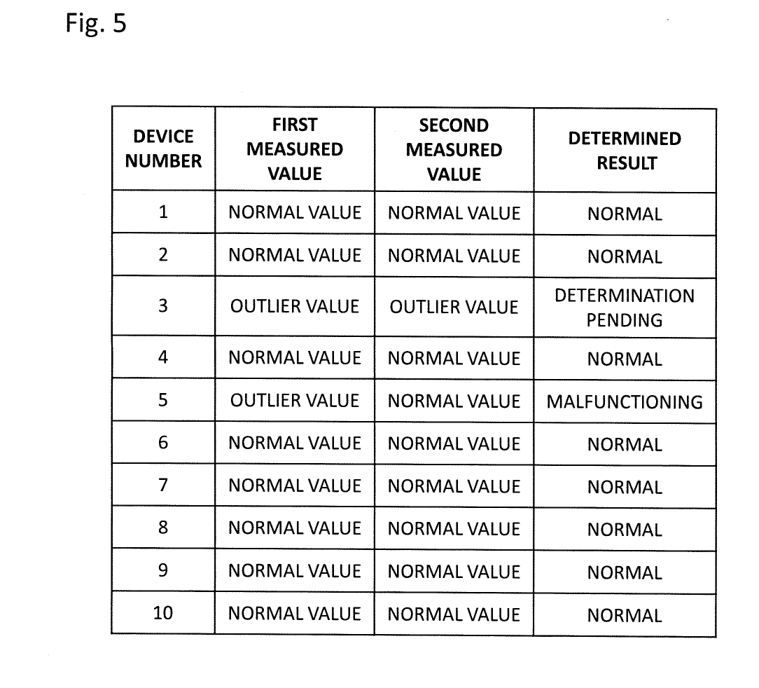

The determination circuit 114 determines malfunctioning devices, based on the result of classification of the first measured values into the normal values and the outlier values by the first classification circuit 112, and the result of classification of the second measured values into the normal values and the outlier values by the second classification circuit 113. FIG. 5 is a table showing an example of determination made by the determination circuit 114 of FIG. 1. FIG. 5 shows an exemplary result of determining whether or not each of ten devices is malfunctioning. If both first measured values and second measured values of a device are normal values, then the device is normal. If first measured values of a device are outlier values, and second measured values of the device is normal values, then the device is malfunctioning. If both first measured values and second measured values of a device are outlier values, then it is not possible to determine whether or not the device is malfunctioning, so the determination is made pending (not determined). If first measured values of a device are normal values, and second measured values of the device are abnormal values, due to, for example, a computing error, then exceptionally, the determination is made pending. In such a manner, the determination circuit 114 determines that the device having the outlier first measured values and the normal second measured values, to be a malfunctioning device. As a result, even when a device is properly functioning and input values are abnormal, it is possible to avoid incorrect determination that the device is malfunctioning, and detect actually malfunctioning device.

The controller 115 controls operations of the other components of the malfunction detection apparatus 110. The controller 115 may execute at least some of computations of the first classification circuit 112, the second classification circuit 113, and the determination circuit 114, on the memory 116. The memory 116 may temporarily store the input values and the output values of the devices 100-1 to 100-N.

The display apparatus 120 is, for example, a liquid crystal monitor, and displays the result of determination outputted from the determination circuit 114.

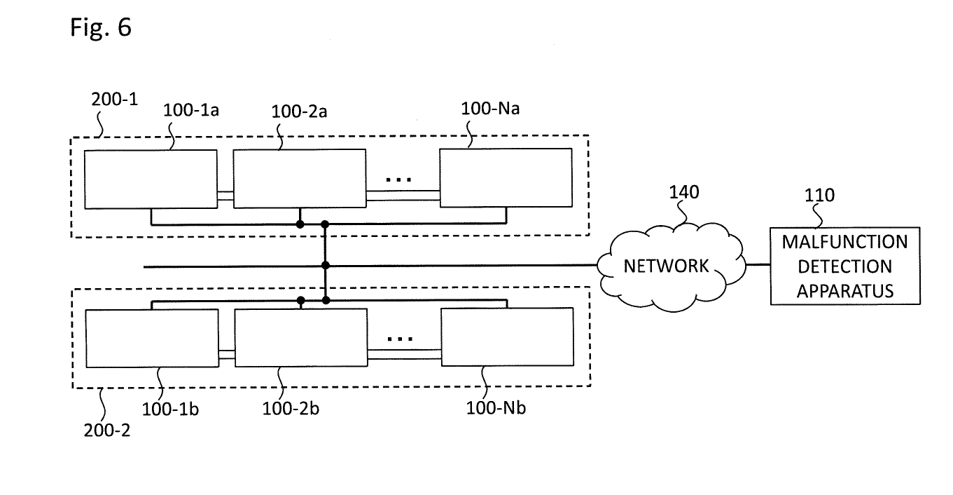

FIG. 6 is a block diagram showing an exemplary application of the malfunction detection system of FIG. 1 to a system including trains 200-1 and 200-2. The train 200-1 includes devices 100-1a to 100-Na that are secondary battery cells or motor devices, and the train 200-2 includes devices 100-1b to 100-Nb that are secondary battery cells or motor devices. The devices 100-1a to 100-Na, 100-1b to 100-Nb are connected to the malfunction detection apparatus 110 via a network 140. Each of the devices 100-1a to 100-Na, 100-1b to 100-Nb is configured in a manner similar to those of the devices 100-1 to 100-N of FIG. 1. The first sensor and the second sensor of each of the devices 100-1a to 100-Na, 100-1b to 100-Nb may measure, for example, the above-mentioned physical quantities related to the secondary battery cell or the motor device provided in each vehicle, or measure physical quantities related to other targets.

Referring to FIG. 6, each of the devices 100-1a to 100-Na, 100-1b to 100-Nb transmits the measured input values and output values to the malfunction detection apparatus 110 via the network 140. Each of the devices 100-1a to 100-Na, 100-1b to 100-Nb may use a mobile communication apparatus to transmit the measured input values and output values, at any time, regardless of whether the trains 200-1 and 200-2 are running or stopped. If the determination circuit 114 of the malfunction detection apparatus 110 determines that any one of the devices is malfunctioning, then the maintenance plan of the device, such as repair or replacement, is updated according to the determination. For example, there is an advantageous effect of making a maintenance plan in advance, so as to promptly perform the maintenance work when a train traveling on a route arrives at a railway yard.

Referring to FIG. 6, in addition, each of the devices 100-1a to 100-Na, 100-1b to 100-Nb may temporarily store the measured input values and output values in a storage device provided in each vehicle, and while the trains 200-1 and 200-2 is stopped at a station, each of the devices 100-1a to 100-Na, 100-1b to 100-Nb may transmit the stored values using a fixed communication apparatus provided at the station. There is an advantageous effect that, when the determination circuit 114 of the malfunction detection apparatus 110 determines that any one of the devices is malfunctioning, the maintenance plan of the device, such as repair or replacement, is updated according to the determination.

As described above, according to the first embodiment, the apparatus measures input values to the devices and output values from the devices, applies the OCSVM to the combinations of the measured input values and output values (first measured values) to classify these values into the normal values and the outlier values, applies the OCSVM to the measured input values (second measured values) to classify these values into the normal values and the outlier values, and determines whether or not each device is malfunctioning based on the results of classifications of the first measured values and the second measured values. Therefore, even when a device is properly functioning and input values are abnormal, it is possible to avoid incorrect determination that the device is malfunctioning, and detect actually malfunctioning device. Accordingly, it is possible to detect malfunction of a device with higher accuracy than that of the prior art.

According to the first embodiment, by using the one class nu-support vector machine as the multivariable analysis method, it is possible to appropriately classify normal values and outlier values of even devices having nonlinear characteristics.

According to the malfunction detection system of the first embodiment, it is possible to collect input values and output values of the devices 100A-1 to 100A-N in real time using the transmitter circuits 103-1 to 103-N and the receiver circuit 111.

### Second Embodiment

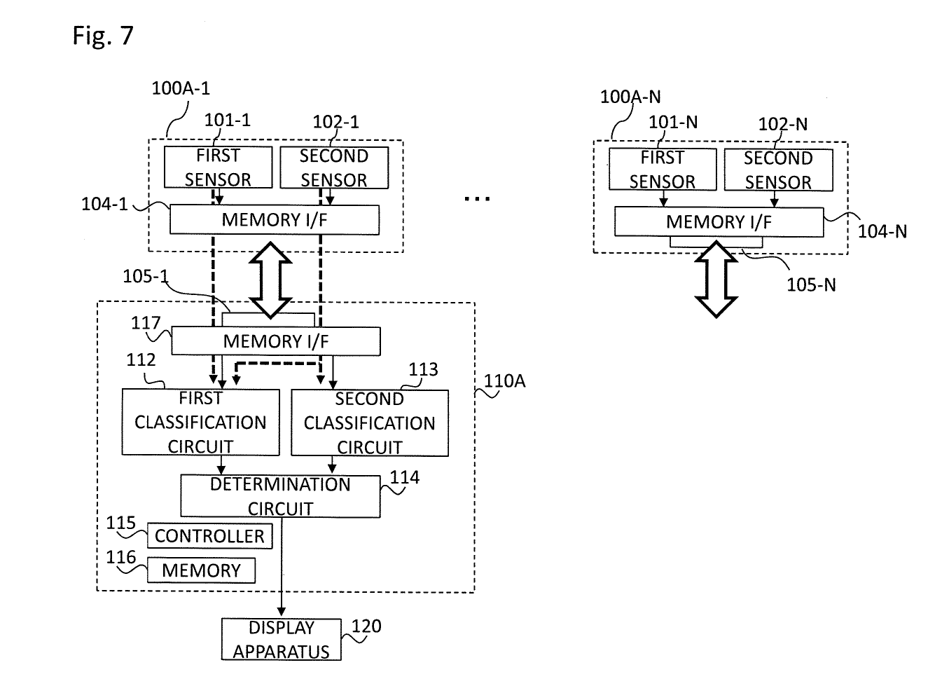

FIG. 7 is a block diagram showing a configuration of a malfunction detection system according to a second embodiment of the present invention. Hereinafter, a description will be given focusing on a difference from the malfunction detection system according to the first embodiment. Detailed description on the same components as those of the first embodiment will be omitted.

The malfunction detection system of FIG. 7 includes a plurality of devices 100A-1 to 100A-N, a malfunction detection apparatus 110A, and a display apparatus 120.

The devices 100A-1 to 100A-N are provided with memory interfaces (I/F) 104-1 to 104-N, instead of the transmitter circuits 103-1 to 103-N of the devices 100-1 to 100-N of FIG. 1, the memory interfaces (I/F) 104-1 to 104-N receiving removable memories 105-1 to 105-N, respectively. Hereinafter, their configuration and operation will be described with reference to the device 100A-1. The first sensor 101-1 measures at least one output value from the device 100A-1, and writes the measured output value into the removable memory 105-1 through the memory interface 104-1. The second sensor 102-1 measures at least one input value to the device 100A-1, and writes the measured input value to the removable memory 105-1 through the memory interface 104-1. The other devices 100A-2 to 100A-N are also configured and operate in the same manner as that of the device 100A-1.

The removable memories 105-1 to 105-N are any removable storage devices, such as a magnetic storage device like a hard disk drive, a semiconductor storage device including various memory cards, and the like.

The malfunction detection apparatus 110A is provided with a memory interface (I/F) 117, instead of the receiver circuit 111 of the malfunction detection apparatus 110 of FIG. 1, the memory interface (I/F) 117 receiving the removable memories 105-1 to 105-N. The malfunction detection apparatus 110A reads the input values and the output values measured by the devices 100A-1 to 100A-N, from the removable memories 105-1 to 105-N through the memory interface 117, respectively.

The input values and the output values are read as follows: for example, an operator removes the removable memories 105-1 to 105-N from the respective devices 100A-1 to 100A-N, and sequentially connects the removable memories 105-1 to 105-N to the malfunction detection apparatus 110A. FIG. 7 shows a state in which the removable memory 105-1 is removed from the device 100A-1 and connected to the malfunction detection apparatus 110A. For example, we consider a case where the devices 100A-1 to 100A-N are secondary battery cells or motor devices mounted on a train. In this case, when the train arrives at the yard, an operator may collect the removable memories 105-1 to 105-N from the respective devices mounted on the train, uses the malfunction detection apparatus 110A to sequentially read input values and output values from the removable memories 105-1 to 105-N, and then, return the removable memories 105-1 to 105-N to the devices 100A-1 to 100A-N.

The malfunction detection apparatus 110 transmits the output values of the devices 100A-1 to 100A-N (measured results of the first sensors 101-1 to 101-N) read from the removable memories 105-1 to 105-N, to the first classification circuit 112. In addition, the malfunction detection apparatus 110 transmits the input values of the devices 100A-1 to 100A-N (measured results of the second sensors 102-1 to 102-N) read from the removable memories 105-1 to 105-N, to both the first classification circuit 112 and the second classification circuit 113.

The malfunction detection apparatus 110A may temporarily store the input values and output values read from the removable memories 105-1 to 105-N, into the memory 116, until the input values and the output values from all the devices 100A-1 to 100A-N are obtained.

The first classification circuit 112, the second classification circuit 113, and the determination circuit 114 of the malfunction detection apparatus 110A operate in a manner similar to those of the corresponding components of the malfunction detection apparatus 110 of the first embodiment.

According to the malfunction detection system of the second embodiment, by transmitting the input values and the output values of the devices 100A-1 to 100A-N to the malfunction detection apparatus 110A through the removable memories 105-1 to 105-N, it is possible to configure a malfunction detection system at low cost without constructing a communication network. It is possible to collect the input values and the output values of the devices 100A-1 to 100A-N in a manner similar to that in the first embodiment, for example, without communication over a network, and even when a device is properly functioning and input values are abnormal, it is possible to avoid incorrect determination that the device is malfunctioning, and detect actually malfunctioning device. Accordingly, it is possible to detect malfunction of a device with higher accuracy than that of the prior art.

For example, when the malfunction detection apparatus 110A cannot be connected to the devices 100A-1 to 100A-N over a network, and it is difficult to carry the malfunction detection apparatus 110A, an operator carries the removable memories 105-1 to 105-N, and thus, the malfunction detection apparatus 110A can obtain input values and output values of the devices 100A-1 to 100A-N.

On the other hand, when the malfunction detection apparatus 110A is configured as a portable notebook computer, tablet terminal, or the like, the malfunction detection apparatus 110A may be sequentially connected to the devices 100A-1 to 100A-N via a cable, instead of using the removable memories 105-1 to 105-N.

### Third Embodiment

Hereinafter, a malfunction detection system according to a third embodiment will be described focusing on a difference from the malfunction detection apparatus according to the first embodiment. Detailed description on the same components as those of the first embodiment will be omitted.

The malfunction detection system according to the third embodiment is configured in a manner similar to that of the malfunction detection system according to the first embodiment (FIG. 1).

The malfunction detection apparatus 110 receives the measured input values and the measured output values from the devices 100-1 to 100-N every moment, and repeats classification into the normal values and the outlier values, and determination of malfunctioning devices, repeatedly every time interval of a predetermined time length. The malfunction detection apparatus 110 finally determines malfunctioning devices, based on results of the repeated classification and determination. The first classification circuit 112 obtains the first measured values from each of the plurality of devices 100-1 to 100-N, and classifies the first measured values of the respective devices into the normal first measured values and the outlier first measured values, repeatedly every time interval of the predetermined time length. The second classification circuit 113 obtains the second measured values from each of the plurality of devices 100-1 to 100-N, and classifies the second measured values of the respective devices into the normal second measured values and the outlier second measured values, repeatedly every time interval of the predetermined time length.

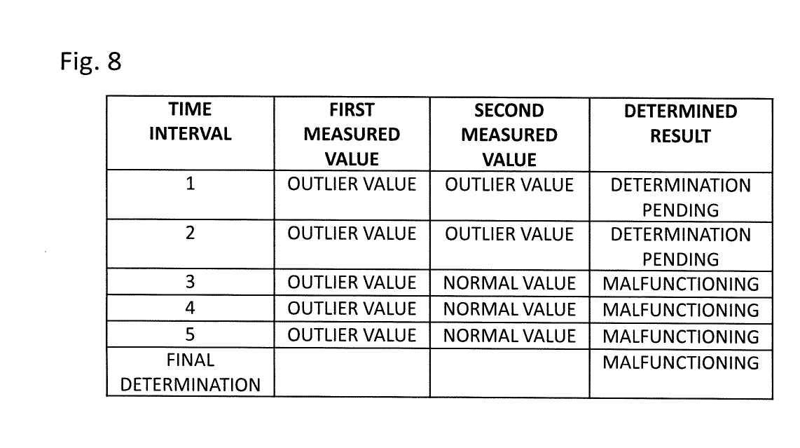

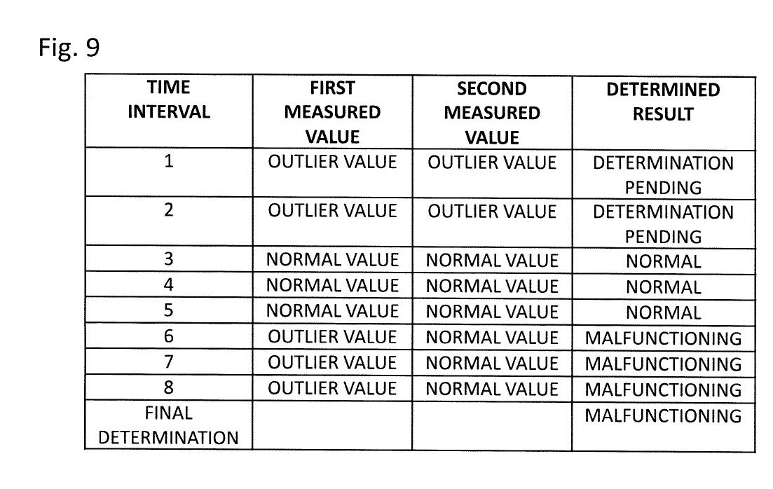

FIG. 8 and FIG. 9 are diagrams showing examples of determination for a device in a case where the determination is repeated every time interval.

For example, according to the case shown in FIG. 8, in time intervals 1 and 2, both the first measured value and the second measured value are outlier values, and the determination circuit 114 makes determination pending. In the subsequent time intervals 3 to 5, the first measured value is an outlier value and the second measured value is a normal value, and the determination circuit 114 determines that the device is malfunctioning. The determination circuit 114 stores the results of the repeated determinations. Since the device, on which the determination was made pending in the time intervals 1 and 2, is repeatedly determined to be malfunctioning in the consecutive time intervals 3 to 5, the determination circuit 114 finally determines that the device is malfunctioning.

In addition, for example, according to the case shown in FIG. 9, in time intervals 1 and 2, both the first measured value and the second measured value are outlier values, and the determination circuit 114 makes determination pending. In the subsequent time intervals 3 to 5, both the first measured value and the second measured value are normal values, and the determination circuit 114 determines that the device is properly functioning. Further, in the sequent time intervals 6 to 8, the first measured value is an outlier value, and the second measured value is a normal value, and the determination circuit 114 determines that the device is malfunctioning. The determination circuit 114 stores the results of the repeated determinations. Since the device, on which the determination was made pending or which was determined to be properly functioning in the time intervals 1 to 5, is repeatedly determined to be malfunctioning in the consecutive time intervals 6 to 8, the determination circuit 114 finally determines that the device is malfunctioning.

Therefore, with such a configuration, it is possible to reduce the number of devices, on which the determination is made pending whether the device is malfunctioning, and finally, for any one of the devices, correctly determine whether the device is properly functioning or malfunctioning. In addition, it is possible to reduce incorrect determination that the device is properly functioning when no abnormality occurs dependent on the second measured values, and thus, correctly determines malfunctioning devices.

In the case where there are both time intervals in which a device is determined to be properly functioning, and time intervals in which the device is determined to be malfunctioning, or in the case where the device is determined to be malfunctioning over a predetermined number of consecutive time intervals, the method for finally determining that the device is malfunctioning is configured in an appropriate manner in accordance with the characteristics of the devices 100-1 to 100-N as detection targets. The above-described examples of determination correspond to the case where the devices 100-1 to 100-N are the secondary batteries, and they are configured based on the nature that abnormality does not occur in a time interval of a zero current, and abnormality occurs in a time interval of a non-zero current, the current being a second measured value.

In addition, the malfunction detection apparatus 110 of the third embodiment may be configured to store the history of the past measured input values and output values into the memory 116, and classify these values into the normal values and the outlier values based on the present and past input values and output values. By considering the past input values and output values classified as normal values, it is possible to improve the accuracy in classification of the current input values and output values into normal values or outlier values.

In addition, for example, the determination circuit 114 may calculate a probability that each of the devices 100-1 to 100-N is determined to be malfunctioning, based on the results of the repeated determinations, and prioritize and update the maintenance plan of devices, such as repair or replacement, in the descending order of the probability.

### INDUSTRIAL APPLICABILITY

The present invention can be used, for example, to detect malfunction of a plurality of secondary battery cells or a plurality of motor devices on railway vehicles.

### REFERENCE SIGNS LIST

100-1 to 100-N, 100-1a to 100-Na, 100-1b to 100-Nb, 100A-1 to 100A-N: DEVICE,
101-1 to 101-N: FIRST SENSOR,
102-1 to 102-N: SECOND SENSOR,
103-1 to 103-N: TRANSMITTER CIRCUIT,
104-1 to 104-N: MEMORY INTERFACE (I/F),
105-1 to 105-N: REMOVABLE MEMORY,
110, 110A: MALFUNCTION DETECTION APPARATUS,
111: RECEIVER CIRCUIT,
112: FIRST CLASSIFICATION CIRCUIT,
113: SECOND CLASSIFICATION CIRCUIT,
114: DETERMINATION CIRCUIT,
115: CONTROLLER,
116: MEMORY,
117: MEMORY INTERFACE (I/F),
120: DISPLAY APPARATUS,
131: NORMAL MEASURED VALUE,
132: MEASURED VALUE OBTAINED WHEN DEVICE ITSELF IS MALFUNCTIONING,
133: MEASURED VALUE OBTAINED WHEN INPUT VALUES ARE ABNORMAL,
140: NETWORK,
200-1 to 200-2: TRAIN.

1. A malfunction detection apparatus for detecting a malfunctioning device among a plurality of devices, the malfunction detection apparatus comprising:
a first classification circuit that obtains first measured values from each one device of the plurality of devices, the first measured values of the one device including at least one input value to the one device and at least one output value from the one device, and classifies the first measured values of the plurality of devices into normal first measured values and outlier first measured values using a predetermined multivariable analysis method;
a second classification circuit that obtains second measured values from each one device of the plurality of devices, the second measured values of the one device including at least one input value to the one device, and classifies the second measured values of the plurality of devices into normal second measured values and outlier second measured values using the multivariable analysis method; and
a determination circuit that determines a device having the outlier first measured values and the normal second measured values, to be a malfunctioning device, among the plurality of devices.

2. The malfunction detection apparatus as claimed in claim 1, wherein the multivariable analysis method is a multivariable analysis method using a one class nu-support vector machine.

3. The malfunction detection apparatus as claimed in claim 1, further comprising a receiver circuit that receives the output values from the plurality of devices, from a plurality of first sensors measuring the output values from the plurality of devices, and receives the input values to the plurality of devices, from a plurality of second sensors measuring the input values to the plurality of devices.

4. The malfunction detection apparatus as claimed in claim 3,
wherein the first classification circuit obtains the first measured values from each one device of the plurality of devices, and classifies the first measured values of the plurality of devices into normal first measured values and outlier first measured values, repeatedly every time interval of a predetermined time length;
wherein the second classification circuit obtains the second measured values from each one device of the plurality of devices, and classifies the second measured values of the plurality of devices into normal second measured values and outlier second measured values, repeatedly every time interval of the predetermined time length, and
wherein the determination circuit determines a device having the outlier first measured values and the normal second measured values over a plurality of successive time intervals, to be a malfunctioning device.

5. The malfunction detection apparatus as claimed in claim 1, further comprising an interface that receives a storage medium which is removable,
wherein the input values to the plurality of devices and the output values from the plurality of devices are read from the storage medium.

6. An malfunction detection system comprising:
a plurality of devices,
a plurality of first sensors that measure output values from the plurality of devices, respectively;
a plurality of second sensors that measure input values to the plurality of devices, respectively; and
a malfunction detection apparatus for detecting a malfunctioning device among the plurality of devices,
wherein the malfunction detection apparatus comprises:
a first classification circuit that obtains first measured values from each one device of the plurality of devices, the first measured values of the one device including at least one input value to the one device and at least one output value from the one device, and classifies the first measured values of the plurality of devices into normal first measured values and outlier first measured values using a predetermined multivariable analysis method;
a second classification circuit that obtains second measured values from each one device of the plurality of devices, the second measured values of the one device including at least one input value to the one device, and classifies the second measured values of the plurality of devices into normal second measured values and outlier second measured values using the multivariable analysis method; and
a determination circuit that determines a device having the outlier first measured values and the normal second measured values, to be a malfunctioning device, among the plurality of devices.

7. The malfunction detection system as claimed in claim 6,
wherein each one device of the plurality of devices is a secondary battery cell,
wherein each one first sensor of the plurality of first sensors measures at least one of a terminal voltage and a temperature of a secondary battery cell, and
wherein each one second sensor of the plurality of second sensors measures at least one of a charging current, a charged percentage, and an air temperature of a secondary battery cell.

8. The malfunction detection system as claimed in claim 6,
wherein each one device of the plurality of devices is a motor device,
wherein each one first sensor of the plurality of first sensors measures at least one of a rotational speed, operation sound, vibration, and a temperature of a motor device, and
wherein each one second sensor of the plurality of second sensors measures at least one of an input current, an input voltage, and an air temperature of a motor device.
